(19) United States
(12) Patent Application Publication
(10) Pub. No.: US 2015/0201525 A1
(43) Pub. Date: Jul. 16, 2015

(54) EFFICIENT ELECTRONIC COMPONENT HEAT SINK

(71) Applicant: Panasonic Automotive Systems Company of America, Division of Panasonic Corporation of North America, Peachtree City, GA (US)

(72) Inventor: GERALD TANG-KONG, NEWNAN, GA (US)

(73) Assignee: Panasonic Automotive Systems Company of America, Division of Panasonic Corporation of North America, Peachtree City, GA (US)

(21) Appl. No.: 14/154,870

(22) Filed: Jan. 14, 2014

(51) Int. Cl. H05K 7/20; H05K 9/00

(52) U.S. Cl. CPC H05K 7/2039; H05K 9/00

(57) ABSTRACT

A heat sink for an electronic component includes a plurality of substantially planar fins extending from a base. At least two adjacent ones of the fins define an angle therebetween of greater than five degrees.

### BACKGROUND OF THE INVENTION

1. Field of the Invention

The present invention relates to a heat sink, and, more particularly, to a heat sink for dissipating heat from a microprocessor or similar device.

2. Description of the Related Art

Heat sinks are known to physically engage and carry heat away from electronic components that otherwise may be damaged by the heat. The heat sink typically is made of aluminum and has a base with a surface that contacts the electronic component. The heat sink also typically has a series of fins extending from the base in a direction away from the electronic component. The fins provide a large surface area within a limited three-dimensional space to thereby increase the rate of convection of heat from the heat sink to the air.

### SUMMARY OF THE INVENTION

The invention may provide a heat sink wherein the fins fan out away from the large heater spreader at the base of the heat sink. That is, the distance between adjacent fins increases along the heights of the fins. The increased distance between adjacent fins may enable the fins to have greater thicknesses. Thus, the heat sink may have higher heat capacity as compared to the equivalent envelope of a traditional heat sink.

In one embodiment, the heat sink is assembled to an electromagnetic interference (EMI) shield. However, assembly methods are possible within the scope of the invention.

The invention comprises, in one form thereof, a heat sink for an electronic component, including a plurality of substantially planar fins extending from a base. At least two adjacent ones of the fins define an angle therebetween of greater than five degrees.

The invention comprises, in another form thereof, a heat sink for an electronic component, including a base having a substantially planar first surface and a substantially planar second surface. A plurality of substantially planar fins extend from the second surface of the base. At least two adjacent ones of the fins define an angle therebetween of greater than five degrees. Each fin includes a respective distal edge. The distal edges may or may not be substantially coplanar.

The invention comprises, in yet another form thereof, a heat sink assembly for an electronic component including a heat sink having a plurality of substantially planar fins extending from a base. At least two adjacent ones of the fins define an angle therebetween of greater than five degrees. An electro-magnetic interference shield includes a throughhole sized to receive the heat sink therein. At least one clip retains the heat sink within the throughhole of the shield.

An advantage of the present invention is that it may provide increased heat dissipation when compared to traditional parallel fin heat sinks both under natural convection conditions and under forced air conditions.

### BRIEF DESCRIPTION OF THE DRAWINGS

The above-mentioned and other features and objects of this invention, and the manner of attaining them, will become more apparent and the invention itself will be better understood by reference to the following description of embodiments of the invention taken in conjunction with the accompanying drawings, wherein:

FIG. 1 is a perspective view of one embodiment of a heat sink of the present invention.

FIG. 2 is a front view of the heat sink of FIG. 1.

FIG. 3 is a perspective view of another embodiment of a heat sink of the present invention.

FIG. 4 is a front view of the heat sink of FIG. 3.

FIG. 5 is a top perspective view of the heat sink of FIG. 3 attached to an EMI shield.

FIG. 6 is a bottom perspective view of the heat sink of FIG. 3 attached to an EMI shield.

### DETAILED DESCRIPTION

The embodiments hereinafter disclosed are not intended to be exhaustive or limit the invention to the precise forms disclosed in the following description. Rather the embodiments are chosen and described so that others skilled in the art may utilize its teachings.

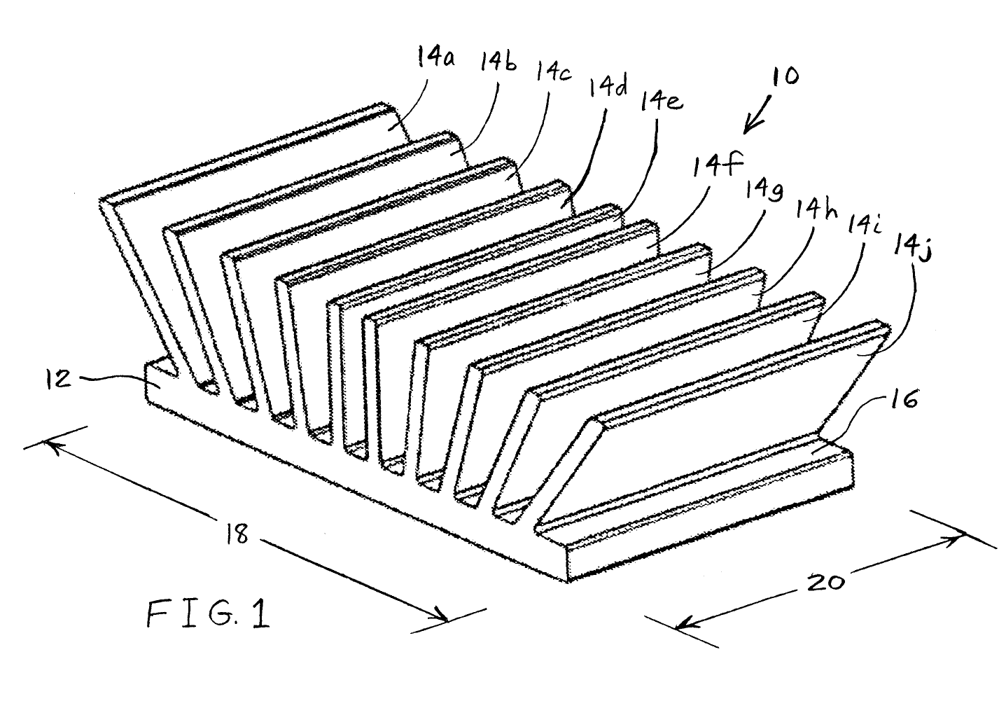

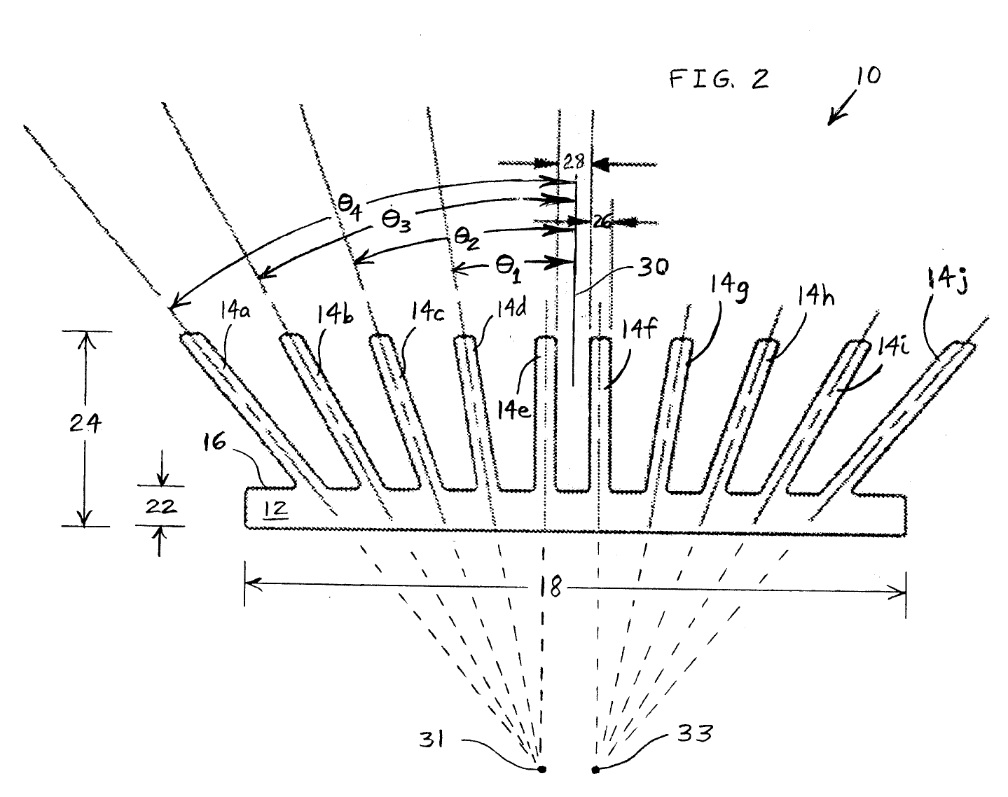

FIG. 1 is a perspective view of one embodiment of a heat sink 10 of the present invention, including a substantially planar and rectangular base 12 and ten substantially planar and rectangular fins 14a-j extending from an upper surface 16 of base 12. Heat sink 10 may be formed of extruded aluminum, or some other material that is a good conductor of heat. Base 12 may have a length 18 of approximately between 36.0 and 46.0 millimeters, a width 20 of approximately between 20.0 and 26.0 millimeters, and a height 22 (FIG. 2) of approximately between 2.0 and 3.0 millimeters. A height 24 of heat sink 10 may be approximately between 10.0 and 14.0 millimeters. Each fin 14 may have a thickness 26 of approximately between 1.2 and 1.4 millimeters. A distance 28 between each pair of adjacent fins 14 may be approximately between 2.0 and 2.4 millimeters at the proximal ends of each fin 14, i.e., at upper surface 16. The upper or distal edges of fins 14a-j may be substantially co-planar.

As best illustrated in FIG. 2, the two innermost or middle fins 14e-f are both substantially perpendicular to upper surface 16 and parallel to each other, separated from each other by distance 28, i.e., approximately between 2.0 and 2.4 millimeters, along their entire heights. However, it the particular embodiment of FIG. 2, none of fins 14a-e are parallel to each other. Rather, fins 14a-e are fanned out from each other. More particularly, an angle θ₁ between fin 14d and a plane 30 perpendicular to the page of FIG. 2 and bisecting heat sink 10 is approximately between eight and twelve degrees; an angle θ₂ between fin 14c and plane 30 is approximately between eighteen and twenty-two degrees; an angle θ₃ between fin 14b and plane 30 is approximately between twenty-eight and thirty-two degrees; and an angle θ₄ between fin 14a and a plane 30 is approximately between thirty-eight and forty-two degrees. Accordingly, an angle between fins 14a and 14b is approximately between eight and twelve degrees; an angle between fins 14b and 14c is approximately between eight and twelve degrees; and an angle between fins 14c and 14d is approximately between eight and twelve degrees.

All of the angles θ₁, θ₂, θ₃ and θ₄ may be defined relative to a common vertex 31. Thus, each of substantially planar fins 14a-e may be co-axial, with an axis that is coincident with vertex 31.

Heat sink 10 may be a minor image of itself about plane 30 such that none of fins 14f-i are parallel to each other. Rather, fins 14f-j are fanned out from each other. More particularly, an angle between fins 14f and 14g is approximately between eight and twelve degrees; an angle between fins 14f and 14h is approximately between eighteen and twenty-two degrees; an angle between fins 14f and 14i is approximately between twenty-eight and thirty-two degrees; and an angle between fins 14f and 14j is approximately between thirty-eight and forty-two degrees. Accordingly, an angle between fins 14g and 14h is approximately between eight and twelve degrees; an angle between fins 14h and 14i is approximately between eight and twelve degrees; and an angle between fins 14i and 14j is approximately between eight and twelve degrees. An angle defined between fins 14a and 14j may be approximately between seventy-six and eighty-four degrees. Thus, respective angles defined between plane 30 and each of fins 14a-j increases with a distance of the fin from plane 30.

All of the angles between fins 14f-j may be defined relative to a common vertex 33. Thus, each of substantially planar fins 14f-j may be co-axial, with an axis that is coincident with vertex 33.

Fins 14a-e have been described above as defining angles having a common vertex 31, and fins 14f-i have been described above as defining angles having a common vertex 33. However, it is also possible within the scope of the invention for at least two of the angles defined by fins 14a-e to not have a common vertex, and/or for at least two of the angles defined by fins 14f-j to not have a common vertex.

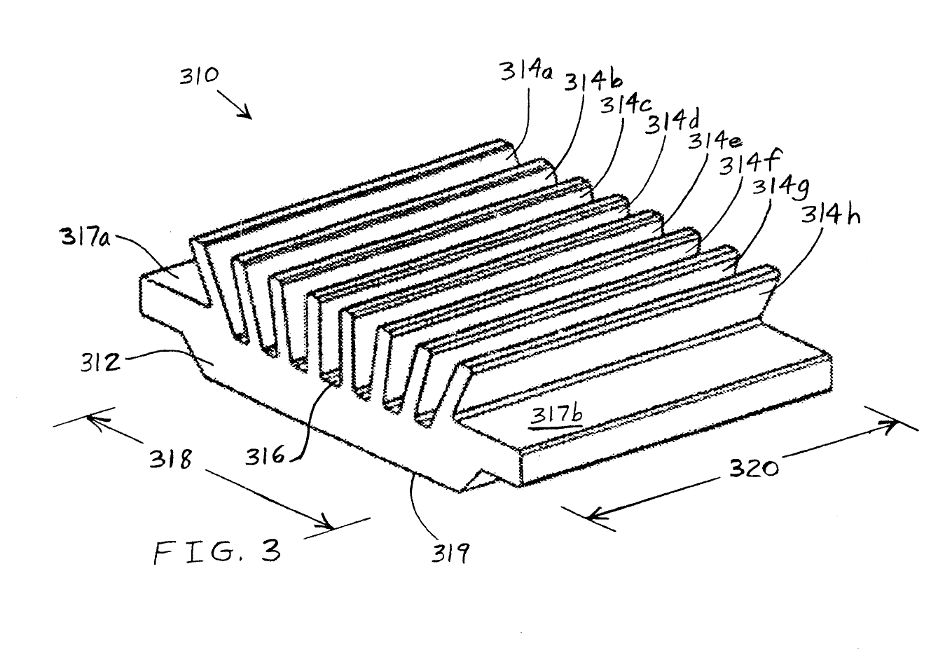

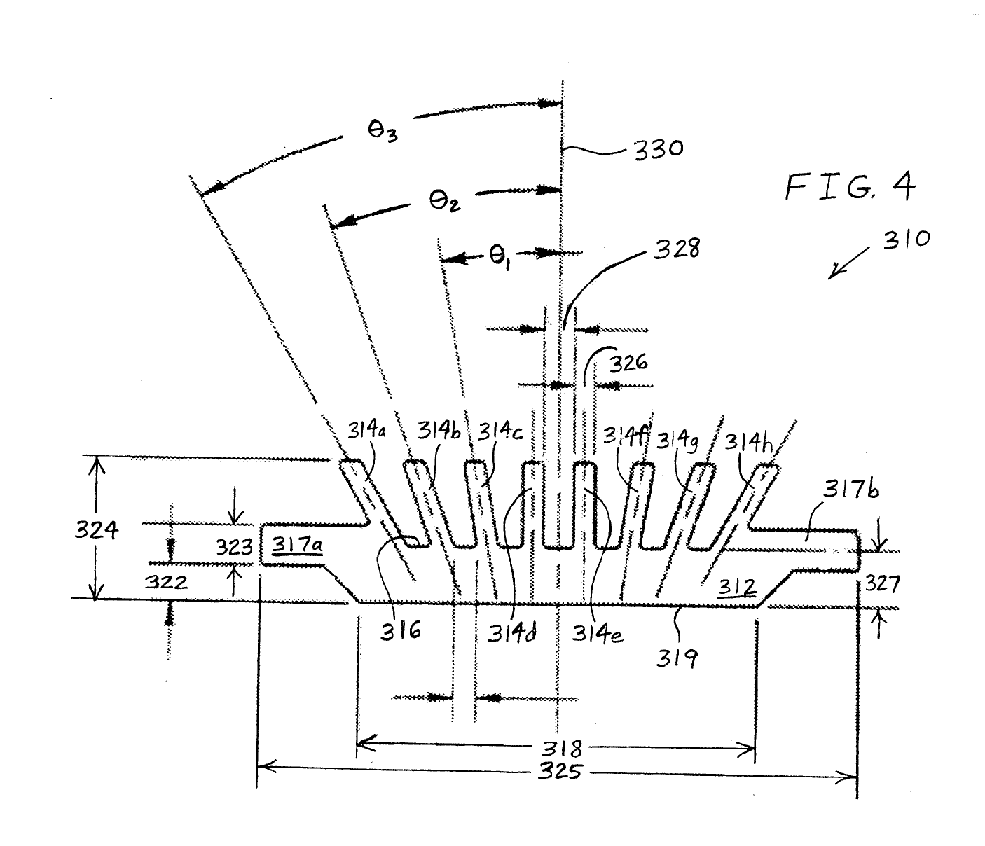

FIG. 3 is a perspective view of one embodiment of a heat sink 310 of the present invention, including a substantially planar and trapezoidal base 312 and eight substantially planar and rectangular fins 314a-h extending from an upper surface 316 of base 312. Two substantially planar and rectangular wings 317a-b extend laterally from upper portions of opposite ends of base 312. Heat sink 310 may be formed of extruded aluminum, or some other material that is a good conductor of heat. A lower surface 319 of base 312 may have a length 318 of approximately between 20.0 and 30.0 millimeters, and a width 320 of approximately between 20.0 and 30.0 millimeters. Base 312 has a height 322 (FIG. 4) of approximately between 6.25 and 11.25 millimeters. Wings 317a-b have a height 323 of approximately between 2.00 and 3.00 millimeters. A height 324 of heat sink 310 may be approximately between 6.25 and 11.25 millimeters. A width 325 of heat sink 310 may be approximately between 33.0 and 42.0 millimeters. A distance 327 between upper surface 326 and a lower surface of base 312 may be approximately between 3.0 and 4.0 millimeters. Each fin 314 may have a thickness 326 of approximately between 1.2 and 1.4 millimeters. A distance 328 between each pair of adjacent fins 314 may be approximately between 1.8 and 2.2 millimeters at the proximal ends of each fin 314, i.e., at upper surface 316. The upper or distal edges of fins 314a-h may be substantially co-planar.

As best illustrated in FIG. 4, the two innermost or middle fins 314d-e are both substantially perpendicular to upper surface 316 and parallel to each other, separated from each other by distance 328, i.e., approximately between 1.8 and 2.2 millimeters, along their entire heights. However, it the particular embodiment of FIG. 4, none of fins 314a-d are parallel to each other. Rather, fins 314a-d are fanned out from each other. More particularly, an angle θ₁ between fin 14c and a plane 330 perpendicular to the page of FIG. 4 and bisecting heat sink 310 is approximately between eight and twelve degrees; an angle θ₂ between fin 314b and plane 330 is approximately between eighteen and twenty-two degrees; an angle θ₃ between fin 314a and plane 330 is approximately between twenty-eight and thirty-two degree. Accordingly, an angle between fins 14a and 14b is approximately between eight and twelve degrees; and an angle between fins 14b and 14c is approximately between eight and twelve degrees.

Heat sink 310 may be a minor image of itself about plane 330 such that none of fins 314e-h are parallel to each other. Rather, fins 314e-h are fanned out from each other. More particularly, an angle between fins 314e and 314f is approximately between eight and twelve degrees; an angle between fins 314e and 314g is approximately between eighteen and twenty-two degrees; and an angle between fins 314e and 314h is approximately between twenty-eight and thirty-two degrees. Accordingly, an angle between fins 14f and 14g is approximately between eight and twelve degrees; and an angle between fins 14g and 14h is approximately between eight and twelve degrees. An angle defined between fins 314a and 314h may be approximately between fifty-six and sixty-four degrees. Thus, respective angles defined between plane 330 and each of fins 314a-h increases with a distance of the fin from plane 330.

Fins 314a-d may define angles having a common vertex (not shown in FIG. 4). Thus, each of substantially planar fins 314a-d may be co-axial, with an axis that is coincident with the common vertex. However, it is also possible within the scope of the invention for at least two of the angles defined by fins 314a-d to not have a common vertex.

Fins 314e-h may define angles having a common vertex (not shown in FIG. 4). Thus, each of substantially planar fins 314e-h may be co-axial, with an axis that is coincident with the common vertex. However, it is also possible within the scope of the invention for at least two of the angles defined by fins 314e-h to not have a common vertex.

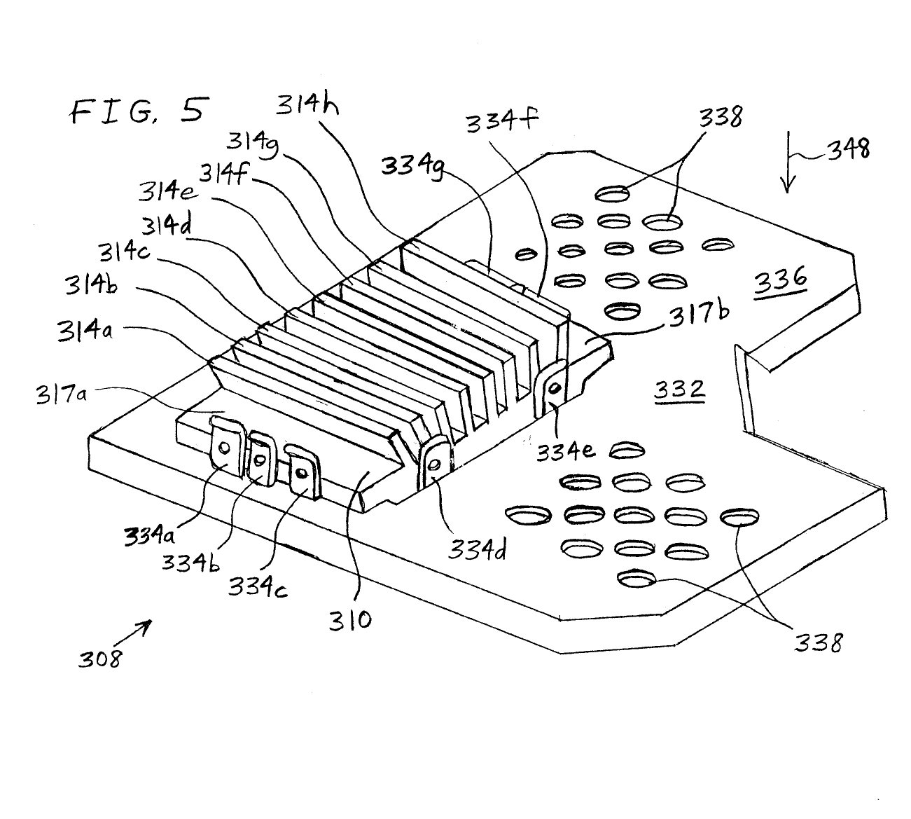

FIG. 5 is a top perspective view of a heat sink assembly 308 including a heat sink 310 attached to an electro-magnetic interference (EMI) shield 332. Shield 332 may include clips 334a-g which attach heat sink 310 to a substantially planar body 336 of shield 332. Shield 332 includes a plurality of throughholes 338 which allow air to pass between the two opposite sides of body 336.

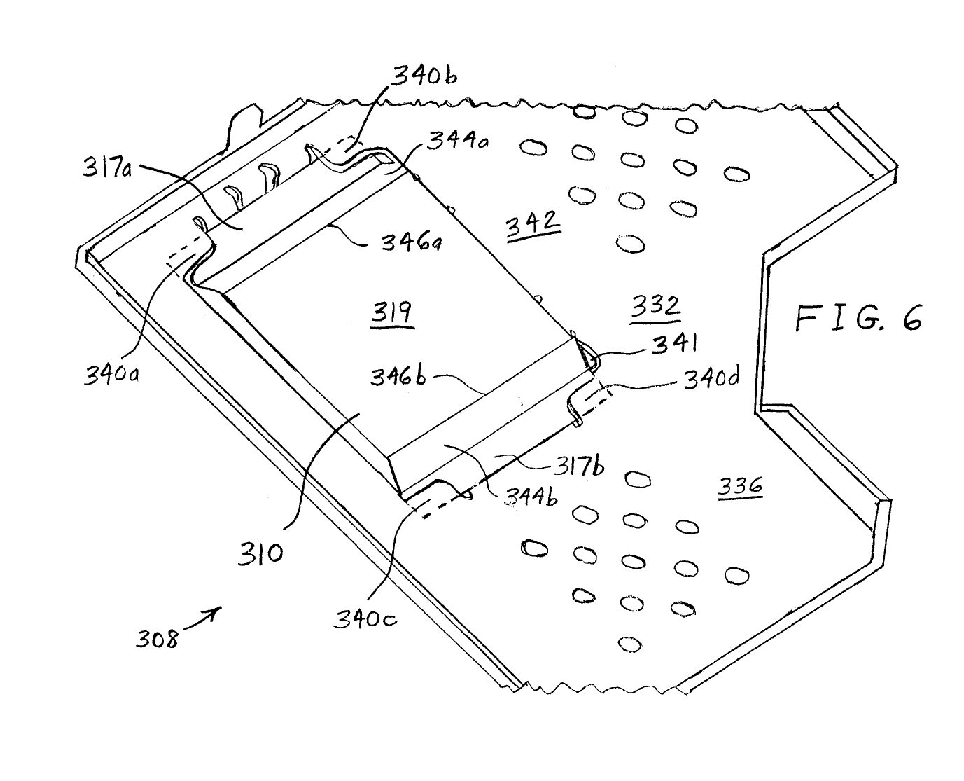

FIG. 6 is a bottom perspective view of heat sink assembly 308 including heat sink 310 attached to EMI shield 332. Shield 332 includes two tabs 340a-b which retain opposite corners of wing 317a. Shield 332 includes another two tabs 340c-d which retain opposite corners of wing 317b. Shield 332 includes a larger, substantially rectangular throughhole 341 sized to snugly receive heat sink 310 therein.

Tabs 340a-d may be disposed at the respective four corners of throughhole 341. Tabs 340a-d may engage respective edge portions of heat sink 310. More particularly, in the specific embodiment of FIG. 6, tabs 340a-d may each engage a respective corner of wings 317a-b.

Bottom, external surface 319 of heat sink 310 may be substantially flush or co-planar with a bottom, surrounding surface 342 of body 336 of shield 332. Bottom surface 319 of heat sink 310 may also be substantially flush or co-planar with a bottom or exposed surface of tabs 340a-d. It is also possible for bottom surface 319 of heat sink 310 to extend slightly (e.g., 1 millimeter or more) beyond bottom surface 342 of body 336 of shield 332 and/or the bottom or exposed surface of tabs 340a-d. Thus, bottom surface 319 of heat sink 310 may easily contact or engage the upper surface of an integrated circuit package that heat sink 310 is to carry heat away from.

Ramped surfaces 342a-b (FIG. 6) of heat sink 310 interconnect bottom surface 319 and wings 317a-b, respectively. Ramped surfaces 342a-b may provide edges 346a-b of bottom surface 319 with obtuse angles, rather than sharper angles that could possibly damage the electronic components that bottom surface 319 is to contact or engage.

During assembly, heat sink 310 may be moved into contact with shield 332 by moving heat sink 310 in direction 348 (FIG. 5) until wings 317a-b engage tabs 340a-d. Then, clips 334a-g may be inserted into shield 332 in order to securely retain heat sink 310 within throughhole 341 and in engagement with shield 332.

In order to increase the surface area of the fins, and thereby increase the heat dissipation of the heat sink, the surface of the fins may be scalloped in one embodiment (not shown). That is, the fins may include grooves or ribs extending in the direction of the heights of the fins, and the grooves or ribs may increase the surface area of the fins.

Examples of specific angles between fins have been illustrated herein. However, it is to be understood that other angles are possible within the scope of the invention, and angles between fins can be optimized for specific applications.

Any of the embodiments described above may be in the form of a thick fin design heat sink for higher heat sinking capacity. However, it is to be understood that the thickness of the fins and the spacing between the fins may vary. Moreover, the heights of the fins may vary depending on the desired heat dissipation characteristics and packaging restraints. The fins can have a natural finish, or may have an anodized black finish for increased heat dissipation.

While this invention has been described as having an exemplary design, the present invention may be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains.

What is claimed is:

1. A heat sink for an electronic component, comprising:
a base; and
a plurality of substantially planar fins extending from the base, at least two adjacent ones of the fins defining an angle therebetween of greater than five degrees.

2. The heat sink of claim 1 wherein at least two of the fins define an angle therebetween of greater than fifty-six degrees.

3. The heat sink of claim 1 wherein at least two of the fins define an angle therebetween of greater than seventy-six degrees.

4. The heat sink of claim 1 wherein an imaginary plane substantially bisects the heat sink, respective angles defined between the plane and each of the fins increasing with a distance of the fin from the plane.

5. The heat sink of claim 1 wherein at least three of the fins define a plurality of angles therebetween having a common vertex.

6. The heat sink of claim 1 wherein at least three of the fins are co-axial.

7. The heat sink of claim 1 wherein the base is substantially planar.

8. A heat sink for an electronic component, comprising:
a base having a substantially planar first surface and a substantially planar second surface; and
a plurality of substantially planar fins extending from the second surface of the base, at least two adjacent ones of the fins defining an angle therebetween of greater than five degrees, each said fin including a respective distal edge, the distal edges being substantially coplanar.

9. The heat sink of claim 8 wherein at least two of the fins define an angle therebetween of greater than sixteen degrees.

10. The heat sink of claim 8 wherein at least two of the fins define an angle therebetween of greater than seventy-six degrees.

11. The heat sink of claim 8 wherein an imaginary plane substantially bisects the heat sink, respective angles defined between the plane and each of the fins increasing with a distance of the fin from the plane.

12. The heat sink of claim 8 wherein at least three of the fins define a plurality of angles therebetween having a common vertex.

13. The heat sink of claim 8 wherein at least three of the fins are co-axial.

14. The heat sink of claim 8 wherein the base is substantially planar.

15. A heat sink assembly for an electronic component, comprising:
a heat sink, including:
a base; and
a plurality of substantially planar fins extending from the base, at least two adjacent ones of the fins defining an angle therebetween of greater than five degrees;
an electro-magnetic interference shield including a throughhole sized to receive the heat sink therein; and
at least one clip retaining the heat sink within the throughhole of the shield.

16. The heat sink assembly of claim 15 wherein the electro-magnetic interference shield includes at least two tabs engaging respective edge portions of the heat sink.

17. The heat sink assembly of claim 16 wherein the at least one clip comprises a plurality of clips, the edge portions of the heat sink being sandwiched between the clips and the tabs.

18. The heat sink of claim 16 wherein the heat sink includes two wings extending from opposite ends of the base, each of the wings being engaged by at least one of the tabs, each of two ramped surfaces interconnecting a respective one of the wings with an external surface of the base.

19. The heat sink of claim 15 wherein an external surface of the base is substantially coplanar with a surrounding surface of the electro-magnetic interference shield.

20. The heat sink of claim 19 wherein the external surface of the base is configured to contact an electronic component and thereby carry heat away from the electronic component.
